(19) United States
(12) Patent Application Publication
(10) Pub. No.: US 2025/0062763 A1
(43) Pub. Date: Feb. 20, 2025

(54) Sensor element and inductive sensor

(71) Applicant: Balluff GmbH, Neuhausen a.d.F. (DE)

(72) Inventor: Umit Koyuncu, Lenningen (DE)

(21) Appl. No.: 18/758,124

(22) Filed: Jun. 28, 2024

(30) Foreign Application Priority Data
Aug. 14, 2023 (DE) 10 2023 121 690.2

(51) Int. Cl. H03K 17/95; G01D 5/20

(52) U.S. Cl. CPC H03K 17/9505; G01D 5/2033; H03K 2017/9527

(57) ABSTRACT

A sensor element (10) has a circuit board (11), which has at least one plane having a printed coil (12). The printed coil (12) has at least one first via (15), which is arranged outside an outermost coil winding (13). A shielding ring (17) is arranged between the first via (15) and the outermost coil winding (13). An inductive sensor has several such sensor elements (10).

The present invention relates to a sensor element. Furthermore, the present invention relates to an inductive sensor, which has several sensor elements.

### PRIOR ART

Inductive sensors have a housing in which a sensor element is installed. The feasible number of windings that a coil of the sensor element has is limited by the surface of the sensor element. It is certainly desirable for the coil to have as many windings as possible, since its signal sensitivity increases with the number of windings. A high degree of signal sensitivity has positive effects on the evaluability, the EMV sensitivity and the switching frequency of the sensor. The feasible number of coil windings is furthermore limited by other elements which have to be arranged on the same plane as the coil. On one hand, these are vias, which are provided to electrically connect several coils of the sensor element arranged on different planes to one another. On the other hand, these are shielding rings which are provided to electrically shield the coils from a surroundings. This is important, in particular, when the inductive sensor is to be installed in a metallic surroundings. The sensor housing regularly does not have a sufficiently high degree of electric conductivity in order to ensure a sufficient degree of shielding from the surroundings, such that a sensor without a shielding ring in the installed state has an unacceptably high degree of sensitivity to interference.

An object of the present invention is to provide a sensor element that has as high a number of coil windings as possible on a predetermined surface. A further object is to provide an inductive sensor which has the sensor element.

### DISCLOSURE OF THE INVENTION

The sensor element has a circuit board. The circuit board has at least one plane on which a printed coil is arranged. The printed coil has at least one first via, which is electrically connected to it. A via is to be understood as an electric through-contacting (plated through-hole) between the planes of the circuit board, which is achieved, in particular, by an inwardly metallised bore in the substrate of the circuit board. The first via is arranged outside an outermost coil winding of the printed coil. It is arranged on the plane of the printed coil and extends through optionally present further planes of the circuit board. A shielding is arranged between the first via and the outer coil windings. The shielding can consist of copper, for example.

This arrangement of the shielding ring has the advantage that the first via can be arranged on the edge of the circuit board. Thus, in comparison to other possible designs of the sensor element, a maximum surface of the circuit board can be covered by the windings of the printed coil, such that a high degree of signal sensitivity of the sensor element is achieved.

Additionally, the arrangement of the first vias on the edge of the circuit board advantageously allows the design of the first via as a half via or half hole (plated half hole). This can be achieved, in particular, by the circuit board initially being produced to be larger than it would reliably be for an installation in the housing of an inductive sensor. All first vias are manufactured as through-contacted bores on the circuit board edge. Then the circuit board is cut to size in such a way that its outer diameter corresponds to the inner diameter of the sensor housing. Here, the first vias are halved, such that they take up a smaller surface area of the circuit board in comparison to complete bores, and a greater proportion of the circuit board surface is accordingly available for the printed coil.

For a good shielding of the printed coil from a metallic surroundings of the sensor element, it is preferred that an electrical connection between a first via and the outer coil winding of the printed coil has an electrical connection point with the shielding ring on a plane. The electrical connection is thus conducted through the shielding without having to be electrically insulated against this. A short circuiting of the electrical connection with the shielding ring enables an optimum electrical shielding of the printed coil.

In principle, the sensor element can be implemented with only one plane and thus also only one printed coil. However, in order to obtain a higher degree of signal sensitivity, it is preferred that the sensor element has several parallel planes. Here, in each case one printed coil is arranged on each of these planes. The printed coils of several planes are respectively electrically connected to one another via vias. Here, a first via respectively serves to contact a printed coil on its outermost coil winding.

Moreover, in each case one shielding ring is arranged on each plane. The shielding rings of the planes are preferably not directly electrically connected to one another. Instead, each shielding ring is only electrically connected to the printed coil of its plane. An electrical connection of the shielding rings to one another is thus only carried out indirectly via the printed coils.

Furthermore, it is preferred that the printed coil has at least one second via, which is arranged inside an innermost coil winding. While in each case a first via is provided for electrically contacting the outermost coil winding of a coil, a second via serves to electrically contact on the innermost coil winding.

It is moreover preferred that the sensor element has more first vias than second vias. Here, to connect the printed coils to one another, only as many first vias are required as the sensor element has second vias. Only this number of first vias is electrically connected to printed coils. The further first vias are electrically insulated from the printed coils. Here, this uses the fact that the first vias are arranged annularly around the printed coils and the shielding rings in the circuit board. If only as many first vias were arranged as are required for electrically contacting the printed coils, a part of the circuit board surface would remain unused in this annular region. By this region being filled with further first vias, the surplus first vias can contribute to the electrical shielding of the printed coils from a metallic surroundings.

Shielding rings which are attached to the edge of a circuit board have to have a specific minimum width. The arrangement of a shielding ring between the printed coil and the first vias has the further advantage that the shielding ring can be designed with a width which, within the plane, is in particular a maximum of 200 μm. Thus, the surface consumption of the shielding ring on the circuit board is minimised, such that more surface is available for coil windings. With a very large coil, a wider shielding ring can admittedly also be chosen. Nevertheless, it is possible that the outer diameter of the first outer winding of the coil is greater than with a sensor element, the vias of which being arranged inside the shielding ring. Thus, the advantages of the sensor element according to the invention are particularly distinct with very small constructions. Yet even with large constructions, the invention offers small advantages.

According to the previously described aspect of the invention, the inductive sensor has several sensor elements. In particular, these sensor elements all have the same circuit board. Thus, it is possible to combine all sensor elements in a single circuit board which can be then installed on the end face of a sensor housing.

In a preferred embodiment of the inductive sensor, it has three sensor elements, which are arranged one above the other in a common circuit board. Here, a first sensor element is set up as the first receiving element. A second sensor element is set up as the second receiving element. It is electrically connected to the first sensor element. Setting up as the receiving element is carried out, in particular, by connecting the respective sensor element to a voltmeter. A third sensor element is arranged between the first sensor element and the second sensor element. It is set up as a transmission element and is electrically insulated from the first sensor element and from the second sensor element. Setting up as the transmission element is carried out, in particular, by the third sensor element being electrically connected to a pulse shaper. Such an inductive sensor makes it possible to recognise all metallic objects without reduction factor with the same switching distance. This property is advantageous in uses in which the material of the objects to be detected can vary or when non-ferrous metals with a high switching distance are to be recorded. The shielding of the printed coils by shielding rings also gives the inductive sensor a high degree of sensitivity when it is installed in metallic material. Its function is not disturbed by strongly electromagnetic fields. It can thus be used in induction curing, for example, or in welding plants.

### BRIEF DESCRIPTION OF THE DRAWINGS

Exemplary embodiments of the invention are depicted in the drawings and are explained in more detail in the following description.

FIG. 1 shows a schematic view of a plane of a sensor element according to the prior art.

FIG. 2 schematically shows how several printed coils in a sensor element are connected to one another according to the prior art.

FIG. 3 schematically shows a view of a plane of a sensor element according to an exemplary embodiment of the invention.

FIG. 4 schematically shows how several printed coils in a sensor element are connected to one another according to an exemplary embodiment of the invention.

FIG. 5 schematically shows an inductive sensor according to an exemplary embodiment of the invention.

### EXEMPLARY EMBODIMENTS OF THE INVENTION

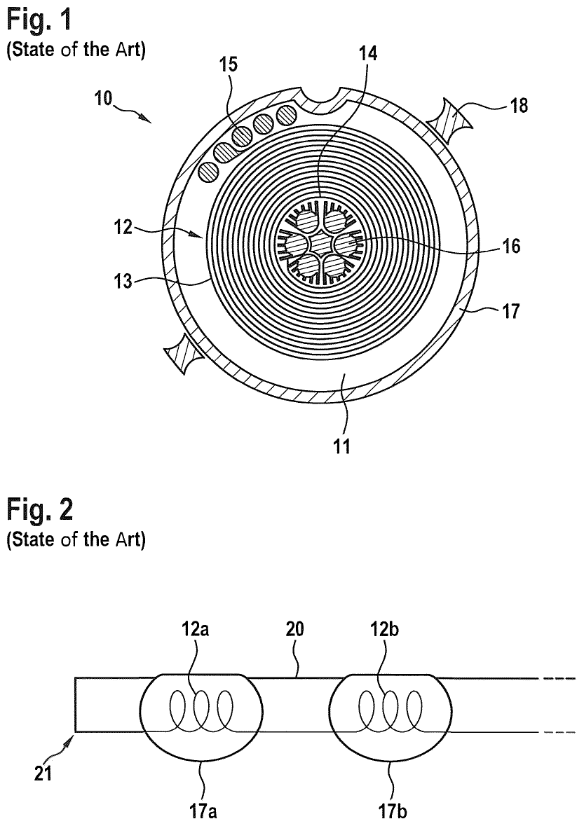

FIG. 1 shows a plane of a sensor element 10 according to the prior art (sensor element of the inductive sensor BES08KP by Balluff GmbH, Germany). A printed coil 12 is arranged on a circular circuit board 11. This has an outermost winding 13 and an innermost winding 14 at which the conductor path of the printed coil 12 ends in each case. Five first vias 15 pass through the circuit board 11 orthogonally to the plane. One of these first vias 15 is electrically connected to the outermost coil winding 13. Five second vias 16 are arranged inside the printed coil 12 and pass through the circuit board 11 orthogonally to the plane. One of the second vias 16 is electrically connected to the innermost coil winding 14. The sensor element has several planes, on which in each case a printed coil 12 is arranged. In each case a pair of a first via 15 and a second via 16 here serves to electrically connect the printed coil 12 of a plane to the printed coil 12 of an adjacent plane. A shielding ring 17 is implemented in the form of an edge metallisation of the circuit board 11. This is partially broken in two positions in order to be able to contact the conductor plate 11 by means of two fastening elements 18 and thus fix them in a sensor housing. Within the plane, the shielding ring has a width of 300 μm. A distance of 100 μm remains clear between the shielding ring 17 and the first vias 15. The first vias 15 have a diameter of 500 μm in each case. A distance of 100 μm again remains clear between the first vias 15 and the outermost coil winding 13. Thus, in the edge region of the circuit board 11, a region with a width of 1.050 μm is not available for the printed coil 12.

FIG. 2 shows how two printed coils 12a, 12b of different planes of the sensor element are connected to each other via the vias 15, 16 not depicted. Furthermore, the shielding rings 17a, 17b of the two printed coils 12a, 12b are depicted. These shielding rings 17a, 17b have an electrical connection 20 on the outer edge of the circuit board 11. All shielding rings of all planes of the sensor element 10 are directly connected to one another via this electrical connection 20. This electrical connection 20 is electrically connected to the system of the printed coils 12 connected via the vias 15, 16 at an individual connection point 21.

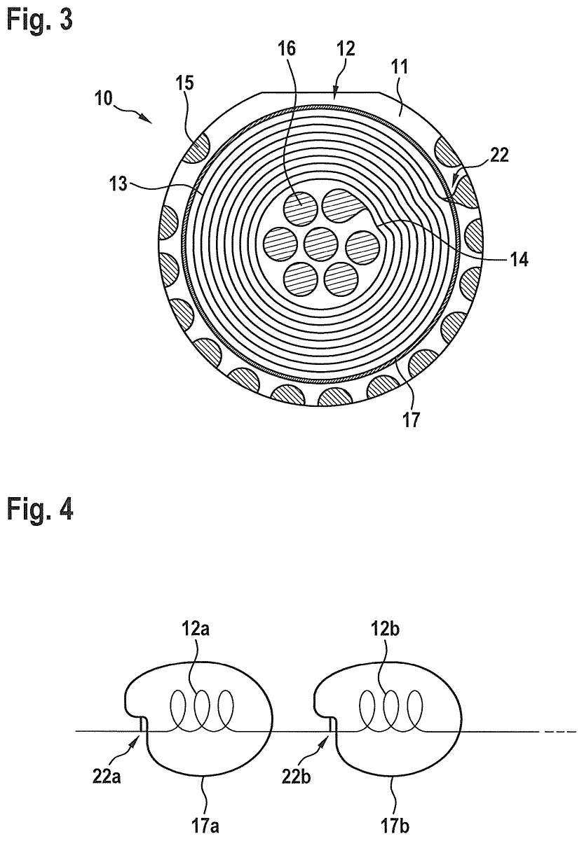

FIG. 3 shows a plane of a sensor element 10 according to an exemplary embodiment of the invention. In contrast to the sensor element 10 according to the prior art, the circuit board 11 is not metallised on its edge. Instead, first vias 15 in the form of half vias are arranged on the edge of the circuit board 11. A printed coil 12 is connected to printed coils 12 of other planes of the sensor element 10 in the same way as in the prior art via a first via 15 connected to the outermost coil winding 13 and a second via 16 connected to the innermost coil winding 14. While this sensor element 10 has six second vias 16, which are arranged around a central point, it has fifteen first vias 15. Of these, however, only six first vias 15 serve to contact printed coils 12, while the remaining nine first vias 15 are not connected to one of the printed coils 12 and instead electrically shield these from the surroundings. A shielding ring 17 is arranged on the circuit board 11 between the first vias 15 and the outermost coil winding 13. It is short-circuited at a connection point 22 with the connection between the outermost coil winding 13 and a first via 15.

It is depicted in FIG. 4 that the shielding rings 17a, 17b are electrically connected among one another by two printed coils 12a, 12b of different planes in each case at a connection point 22a, 22b per plane to the electrical connection of the printed coils 12a, 12b. A separate electrical connection of the shielding rings 17a, 17, one below the other, as is depicted in FIG. 2 for the prior art, is not required.

By implementing the first vias 15 as half vias, their space requirement on an imaginary axis between the edge of the circuit board 11 and its centre respectively corresponds to their radius and not their diameter. When the bores of the first vias 15 are implemented by the circuit board 11 with the same diameter as in the exemplary embodiment of the prior art, this space requirement is thus only 275 μm. The distance between the first vias and the shielding ring 17 is 100 μm. The shielding ring 17 can be designed with a width of only 100 μm. The distance between the shielding ring 17 and the outermost winding, the printed coil 12, is also 100 μm, such that an annular region with a width of 525 μm around the printed coil 12 is not available for the windings of the printed coil 12. In contrast to the prior art, this width of the unusable edge region of the circuit board 11 could thus be halved.

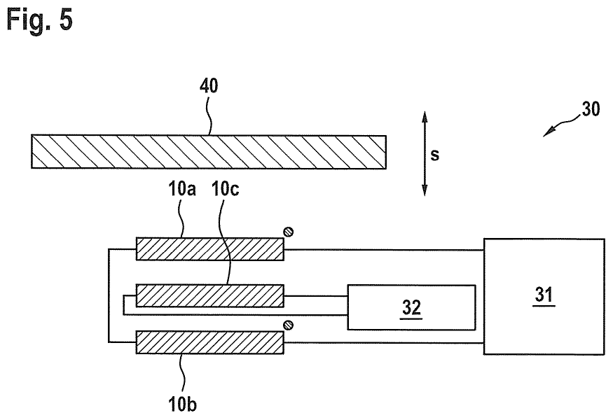

FIG. 5 shows an inductive sensor 30, which is designed as a proximity switch. A first sensor element 10a and a second sensor element 10b are electrically connected to each other. Furthermore, they are respectively connected to a voltmeter 31 for reading the electrical voltage. A third sensor element 10c is arranged between these two sensor elements 10a, 10b. This is connected to a pulse shaper 32 of an oscillator. The first two sensor elements 10a, 10b serve as receiving elements, and the third sensor element 10c serves as a transmission element. When a metallic object 40 is brought close to the inductive sensor 30 and moves along a track s towards the inductive sensor 30, a recognition of the object 40 is carried out when a switching distance is not met.

Below, three exemplary embodiments of the inductive sensor have been compared to one another. Here, in each case sensor elements 10a to 10c have been used, which have an identical number of planes and have a diameter of their circuit board 11 of 18 mm in each case. The circuit board 11 has been installed in a sensor housing, and the inductive sensor has been set to a nominal switching distance of 8 mm. In a first comparative example VB1, sensor elements 10a to 10b have been used, which differ from the sensor element 10 of the prior art, which is depicted in FIGS. 1 and 2, by the absence of the shielding ring 17. In a second comparative example VB2, sensor elements 10a to 10c have been used according to the prior art depicted in FIGS. 1 and 2. In an example B1 according to the invention, sensor elements 10a to 10c have been used, which correspond to the exemplary embodiment of the invention, which is depicted in FIGS. 3 and 4. The oscillator amplitude detected by means of the voltmeter 31 has been respectively measured in three situations. In the first situation, the inductive sensor 30 has not been installed in metallic surroundings, and no object 40 has been brought close to it. In the second situation, the inductive sensor 30 has not been installed in metallic surroundings, and an object 40 has been brought up to the inductive sensor 30 at a distance of 8 mm. In the third situation, the inductive sensor 30 has been installed flush in a surroundings made of high-grade steel, and no object 40 has been brough close to it. The measured oscillator amplitudes are tabulated in Table 1:

TABLE 1

| | VB1 | VB2 | B1 |
|---|---|---|---|
| no object/not installed | 1,000 mV | 1,000 mV | 1,000 mV |
| object/not installed | 900 mV | 990 mV | 950 mV |
| no object/installed | 800 mV | 995 mV | 980 mV |

It can be seen from these values that, in the comparative example VB1, the sensor elements 10a to 10c without the presence of a shielding ring 17 experience a greater influence by the installation than by a metallic object 40 to be recognised. In comparative example VB2, the change of the oscillator amplitude due to the installation is smaller than due to the metallic object 40 to be recognised. Nevertheless, both changes lie close to each other, which makes the evaluation difficult and predisposes the inductive sensor 30 to disturbances. In example B1 according to the invention, the inductive sensor 30 is influenced more strongly by the installation situation than in comparative example VB2. This is unproblematic, however, since there is a significant difference between the oscillator amplitude in the installation position and the oscillator amplitude due to the object 40 to be recognised. This inductive sensor 30 can reliably recognise a metallic object 40 regardless of the surroundings in which it is installed. This is achieved by its sensor elements 10a to 10c having more coil windings with the same diameter of the circuit board 11 than in the second comparative example VB2.

1. A sensor element comprising: a circuit board which has at least one plane having a printed coil, wherein the printed coil has at least one first via, which is arranged outside an outermost coil winding a shielding ring is arranged between the first via and the outermost coil winding.

2. The sensor element, according to claim 1, wherein the first via is implemented as a half via.

3. The sensor element, according to claim 1, wherein an electrical connection between a first via and the outermost coil winding has an electrical connection point to the shielding ring.

4. The sensor element according to claim 1, has several planes, wherein the printed coils of the several planes are each electrically connected to one another via vias.

5. The sensor element, according to claim 4, wherein the shielding rings of the planes are not directly electrically connected to one another.

6. The sensor element according to claim 1, wherein the printed coil has at least one second via, which is arranged inside the innermost coil winding.

7. The sensor element, according to claim 6, has more first vias than the at least one second vias.

8. An inductive sensor, having several sensor elements, comprising: a circuit board which has at least one plane having a printed coil, wherein the printed coil has at least one first via arranged outside an outermost coil winding, and a shielding ring arranged between the first via and the outermost coil winding.

9. The inductive sensor according to claim 8, has three sensor elements arranged one above the other in a common circuit board, wherein
a first sensor element is set up as a first receiving element,
a second sensor element is set up as a second receiving element and is electrically connected to the first sensor element, and
a third sensor element, which is arranged between the first sensor element and the second sensor element, is set up as a transmission element and is electrically insulated from the first sensor element and from the second sensor element.
